(19) United States
(12) Patent Application Publication
(10) Pub. No.: US 2009/0262513 A1
(43) Pub. Date: Oct. 22, 2009

(54) Support frame for supporting a control panel

(75) Inventors: Richard Hosl, Nabburg (DE); Rolf Zettwitz, Forchheim (DE)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Aktiengesellschaft

(21) Appl. No.: 12/386,155

(22) Filed: Apr. 14, 2009

(30) Foreign Application Priority Data
Apr. 16, 2008 (EP) 08007457.8

(51) Int. Cl. H05K 5/02; H02B 1/01; A47B 96/06

(52) U.S. Cl. 361/829; 248/309.1

(57) ABSTRACT

A support frame for supporting a control panel, preferably for completely supporting an operator control and monitoring device, is disclosed. Frame elements form the support frame, the frame elements being embodied as external side surfaces forming a housing part. Securing units fix the control panel essentially inside the support frame. A part of at least one frame element is embodied with a first flange surface for flange-mounting the frame element onto a support arm having a second flange surface.

### CROSS REFERENCE TO RELATED APPLICATIONS

This application claims priority of European Patent Application No. 08007457.8 EP filed Apr. 16, 2008, which is incorporated by reference herein in its entirety.

### FIELD OF INVENTION

The invention relates to a support frame for supporting a control panel, comprising frame elements forming the support frame which are embodied as external side surfaces forming a housing part, and securing means for fixing the control panel essentially inside the support frame. The invention further relates to an operator control and monitoring device having a support frame for supporting a control panel, comprising frame elements forming the support frame which are embodied as external side surfaces forming a housing part, and securing means for fixing the control panel essentially inside the support frame.

### BACKGROUND OF INVENTION

Housings are generally used for the installation of control panels, user interfaces, touch panels, or panel PCs. If operator control and monitoring devices of said kind are to be mounted on a support arm as what are termed standalone operator consoles, according to the prior art the user interfaces or panel PCs are installed in a mounting box. Said mounting box is in turn connected to a support arm either by means of its baseplate, for example, or by means of its rear wall. A support arm of said type enables the user of an industrial machine to operate his/her user interface easily and if necessary swivel it into a position that is advantageous for him/her. Disadvantageous aspects of installing the user interface in a mounting box are that on the one hand the overall weight of a box construction of said kind is relatively high and on the other hand the waste heat generated by, for example, a panel PC cannot be adequately dissipated from the mounting box. Complicated heat dissipation devices such as e.g. fans and ventilation ducts are necessary in order to dissipate the waste heat.

A double-walled housing for industrial panels and panel PCs is disclosed in EP 1 630 643 A2. A housing for accommodating a control panel and/or a computer having a user interface are/is presented. Housings or housing frames of this type are used for installing an accommodated user interface, a touch screen for example, in a switching cabinet door, a wall, a console, or in the aforementioned mounting box for standalone operation. A disadvantage of said double-walled housing for industrial panels and panel PCs is that double-walled housings or frames of this type cannot be combined with a support arm or support arm system without a mounting box.

### SUMMARY OF INVENTION

An object of the present invention is to disclose a housing for a control panel or a display or a panel PC which can be combined with a support arm or support arm system without use of a mounting box.

The object is achieved by means of a housing having a support frame as cited in the introduction, wherein a part of at least one first frame element is embodied with a first flange surface for flange-mounting the first frame element onto a support arm having a second flange surface. By means of the embodiment of a frame element, an aluminum frame embodied as a milled part for example, having a first flange point, a suspended mounting assembly or an adapter point is created for a housing having a support arm or support arm system without the need to integrating the control panel of a panel PC into a mounting housing by means of a mounting frame according to the prior art. An advantageous aspect of this is that an increased amount of heat generation caused by a mounting box and an accumulation of heat resulting therefrom no longer occur. This means that preferably panel PCs can be deployed in a harsh, rugged and high-temperature industrial environment while having an extended service life.

In an advantageous embodiment of the invention the first flange surface is arranged essentially vertically with respect to an operator interface provided by the control panel. The flange surface is therein preferably an integral part of the support frame which is manufactured for example from a pressure die-cast aluminum frame plate or from magnesium or from individual profiles. Owing to the vertical arrangement of the flange surface relative to the operator interface, the control panel subsequently installed in the support frame can be mounted vertically onto the second flange surface of the support arm and is thus easily accessible and easy to use.

In a further advantageous embodiment the flange surface has a cutout to allow lines to be routed through. Supply lines such as a power supply line, a data line and, for example, a separate emergency power-off line can be routed through said cutout and connected to electronics modules required for the control panel or, as the case may be, for a panel PC. The lines can therefore be routed from the interior of a panel PC through the cutout of the flange opening into a tube of the support arm.

In a particularly advantageous embodiment of the invention a connecting means is arranged between the first flange surface and the second flange surface. Said connecting means can be used among other things as an adapter for different support arm systems from different manufacturers. This enables a base device to be mounted onto the most disparate support arm systems with the aid of adapters. A combination with a tilt-adjustable articulated joint between the connecting means and the support arm is also conceivable.

The connecting means is preferably embodied with a retaining arm for supporting an add-on device which is arranged relative to a side surface. By means of, for example, two retaining arms which extend lengthwise on the right and left of the connecting means to one of the side surfaces, add-on devices such as e.g. keypad modules, loudspeakers, haptic input devices, or acoustic signal generators can advantageously be mounted at the side of the control panel. The control panel with its support frame thus represents a base device which can be arbitrarily expanded with add-on devices by way of the retaining arms arranged on the connecting means. A further retaining arm could support, for example, a keyboard which is arranged below the control panel. A modular building-block system is produced by means of the retaining arms arranged on the connecting element.

In a further advantageous embodiment which increases the versatility of a building-block system of said kind, a third frame element has a third flange surface. For the cited base device or a building-block system, the third flange surface creates the possibility of mounting, for example, a panel PC on a pedestal or on a support arm routed to the panel PC from above. In addition a panel PC set up on a pedestal for a first use or operation of an industrial installation can be easily converted with the aid of said third flange surface for a second different use or operation of the industrial installation with changed basic conditions on a support arm positioned above the panel PC.

It is also advantageous for a flange plate to be arranged on the third flange surface, said flange plate being embodied as a module carrier for functional enhancements of the control panel. A USB interface or an access port for a programming device can be arranged on said flange plate, for example. The lines for the USB interface or for connecting the programming device are then likewise routed into the interior of the device through a further cutout in the third flange surface.

It is also advantageous if a cooling surface for cooling a component of an electronics module is coupled to at least one frame element. Since the frame elements or, as the case may be, the complete support frame is usually manufactured from a metallic material, the good thermal conductivity known from metal can be used to conduct the waste heat generated by components into the support frame and thereby cool the component. If a support frame is embodied as a pressure die-cast aluminum frame plate or a milled aluminum part, small pillars or metal pads which are an integral permanent part of the plate can be arranged on said plate and these pillars or metal pads will then make contact with electronic components arranged on a printed circuit board of the electronics module in order to dissipate the heat.

In the case of the operator control and monitoring device cited in the introduction, the object is achieved in that a part of at least one first frame element is embodied with a first flange surface for flange-mounting the first frame element onto a support arm having a second flange surface. By means of the flange surface integrated in the support frame it is possible to dispense with the uneconomic installation of an operator control and monitoring device in a mounting box.

The control panel, the side surfaces and a cover which is placed onto the support frame and arranged in a sealing manner around the first flange surface advantageously form a single structural unit. Said structural unit is embodied in its entirety in such a way that it conforms to the stringent industrial requirements for operator control and monitoring devices. For example, a structural unit of said type can satisfy an IP65 protection class, i.e. the structural unit is protected against splash water on all sides. In addition the cover, implemented for example as a pressure die-cast aluminum housing, forms an inherently stable hood which is inserted in a precisely fitting manner into the support frame and thereby ensures a distribution of the forces occurring at the flange surfaces as a result of the dead weight of, for example, an installed panel PC. With such a housing concept having a cover, in the case of a panel PC as operator control and monitoring device, for example, said panel PC is easily accessible at all times for maintenance or repair interventions.

It is also advantageous if a connecting means is arranged between the first flange surface and the second flange surface, said a connecting means being embodied with retaining arms for supporting add-on devices which are essentially arranged relative to the side surfaces. By means of the retaining arms arranged on the connecting means a flexible building-block system is produced from a base device with arbitrary expansions of add-on devices which can be arranged to the right and left of the base device, for example. A keyboard carrier can also be mounted onto said retaining arms, thereby creating the possibility of arranging a keyboard beneath the operator interface.

Said types of operator control and monitoring devices are preferably embodied with a control panel from a touch screen.

In addition to the positioning of the parts relative to one another, a further function of the flanges is often also to transfer operating forces. In this case the flange surface is preferably structurally embodied with supporting ribs, reinforcing elements or stabilizers.

### BRIEF DESCRIPTION OF THE DRAWINGS

The invention is described and explained in more detail below with reference to the exemplary embodiments illustrated in the figures, in which:

FIG. 1 shows a support frame,

FIG. 2 shows an operator control and monitoring device as a panel PC having add-on devices on a support arm, and

FIG. 3 shows the operator control and monitoring device from FIG. 2 in a rear view.

### DETAILED DESCRIPTION OF INVENTION

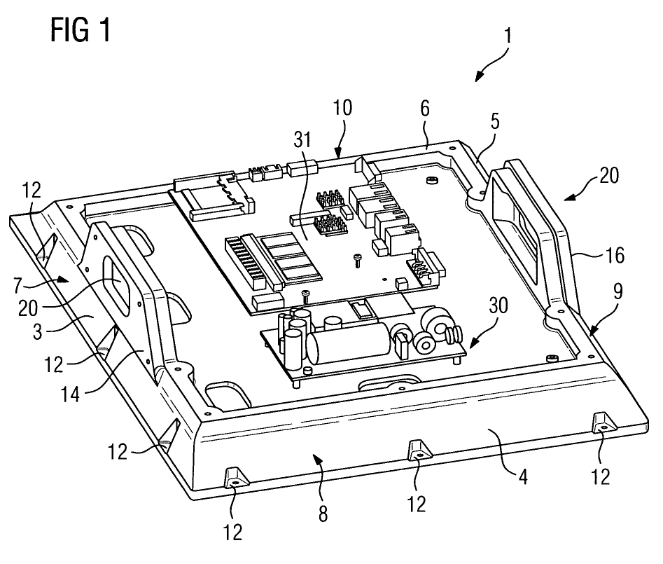

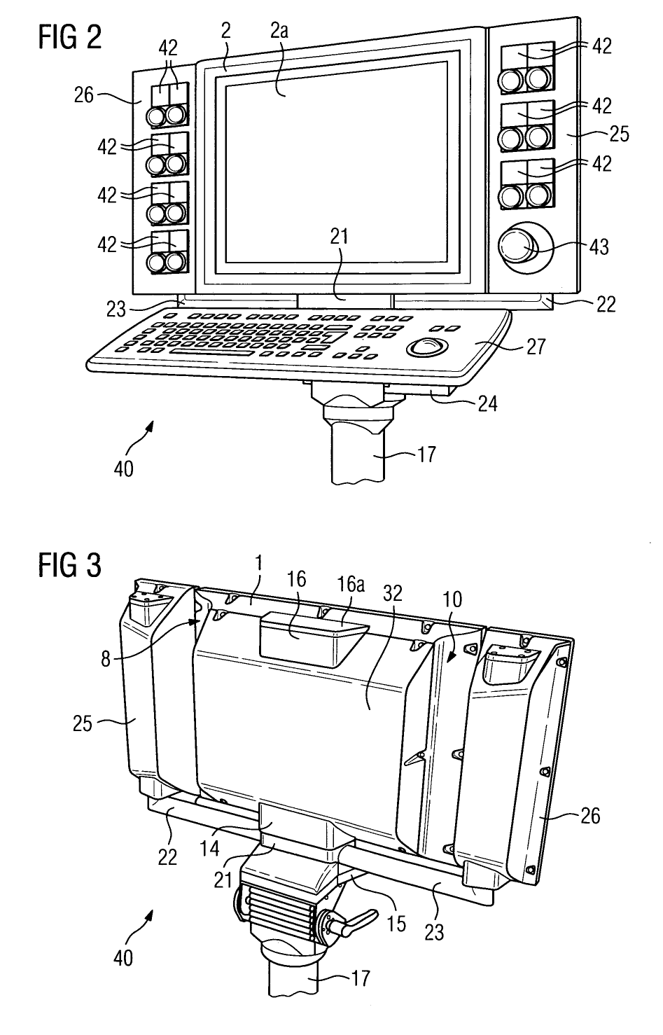

Referring to FIG. 1, a support frame 1 for supporting a control panel 2 (see FIG. 2) is shown, the support frame having a first frame element 3, a second frame element 4, a third frame element 5 and a fourth frame element 6. The rectangular support frame 1 for the control panel 2 is formed by means of said four frame elements. Since this support frame 1 subsequently forms a housing part, the side surfaces of the frame elements are embodied as a first side surface 7, a second side surface 8, a third side surface 9 and a fourth side surface 10. A first flange surface 14 is arranged on the first frame element 3 in the middle of the frame element 3 symmetrically with respect to its ends. Said first flange surface 14 is embodied for the purpose of providing a secure assembly connection to a second flange surface 15 of a support arm 17. Since only the three-dimensional perspective view of the support frame 1 is depicted in FIG. 1, reference is made to FIGS. 2 and 3 for reference signs which cannot be found in FIG. 1.

A third flange surface 16 is arranged on the third frame element 5 which is disposed opposite the first frame element 3. A panel PC installed in the support frame 1 can therefore be adaptively mounted either on a support arm 17 which is embodied as a pedestal or by means of a suspended support arm which approaches the device formed by means of the support frame 1 from above. The first flange surface 14 and the second flange surface 16 each have a cutout 20. Said cutout 20 serves for feeding signal lines to an electronics module 31.

Three securing means 12 which are implemented as holes for retaining screws are recessed in the frame elements around the periphery of the frame in order to allow a control panel to be mounted inside the support frame 1.

The electronics module 31 is arranged inside the support frame 1 on a cooling surface 30. In this case the support frame 1 is embodied as a support frame pressure die-cast aluminum plate.

FIG. 2 shows an operator control and monitoring device 40 which is equipped gas a panel PC having add-on devices 25, 26, 24. The panel PC with its control panel 2 has an operator interface 2a which is embodied as a touch-screen monitor. In a front view onto the panel PC, a first add-on device 25 is arranged via a first retaining arm 22 to the right of its operator interface 2a. The first add-on device 25 has six switch elements 42. By means of switch elements 42 of these type operators are able to control industrial installations in direct key operating mode. An emergency shutdown pushbutton switch 43 is incorporated below the arrangement of the switch elements 42 of the first add-on device 25. The first retaining arm 22 is fixedly joined to a connecting means 21, by means of a welded joint for example. The connecting means 21 forms an adapter which is mounted between the first flange surface 14 known from FIG. 1 and a second flange surface 15 which is visible only in FIG. 3.

In the front view onto the panel PC, a second retaining arm 23 extends to the left, starting from the connecting means 21. A second add-on device 26 having eight further switch elements 42 is arranged on said second retaining arm 23.

A third add-on device 27 which is embodied as a keyboard is arranged below the operator interface 2a of the panel PC by means of a third retaining arm 24 which is shown only indicatively. The entire panel PC, and hence the operator control and monitoring device 40, is mounted by means of the first flange surface 14 of the support frame 1 via the connecting means 21 on a support arm 17 which is embodied as a pedestal.

Referring to FIG. 3, the panel PC known from FIG. 2 is shown as an operator control and monitoring device 40 in a perspective rear view. The panel PC is connected to the connecting means 21 via its first flange surface 14 recessed into the support frame 1 and to the support arm 17 via the second flange surface 15. The embodiment of the first and second retaining arm 22, 23 is clearly recognizable in this rear view. The first and second retaining arms 22 and 23 are attached to the connecting means 21 which is substantially matched to the shape of the first flange surface 14. By way of a right-angled bend in the retaining arms 22, 23, the first and second add-on devices 25, 26 are mounted onto the retaining arms 22, 23 via flange surfaces which are embodied correspondingly smaller. Together with the control panel 2 and the side surfaces 7, 8, 9, 10, a cover 32 forms a structural unit for the panel PC which is embodied as a base device. The cover 32 is arranged in a sealing manner in the support frame 1 and around the flange surfaces 14 and 16. A flange plate 16a is mounted onto the flange surface 16 to serve as a cover. Functional enhancements for the control panel 2 or, as the case may be, for the entire panel PC can optionally be installed in said flange plate 16a. The flange plate 16a therefore serves as a module carrier.

1.-12. (canceled)

13. A support frame for supporting a control panel, comprising:
frame elements forming the support frame, the frame elements being embodied as external side surfaces forming a housing part; and
a securing unit for fixing the control panel inside the support frame,
wherein a part of a first frame element has a first flange surface for flange-mounting the first frame element onto a support arm having a second flange surface.

14. The support frame as claimed in claim 13, wherein the first flange surface is arranged vertically with respect to an operator interface given by the control panel.

15. The support frame as claimed in claim 13, wherein the first flange surface has a cutout to allow lines to be routed through.

16. The support frame as claimed in claim 14, wherein the first flange surface has a cutout to allow lines to be routed through.

17. The support frame as claimed in claim 13, further comprising:
a connecting unit arranged between the first flange surface and the second flange surface.

18. The support frame as claimed in claim 14, further comprising:
a connecting unit arranged between the first flange surface and the second flange surface.

19. The support frame as claimed in claim 15, further comprising:
a connecting unit arranged between the first flange surface and the second flange surface.

20. The support frame as claimed in claim 17, wherein the connecting unit has a retaining arm for supporting an add-on device which is arranged relative to a side surface.

21. The support frame as claimed in claim 18, wherein the connecting unit has a retaining arm for supporting an add-on device which is arranged relative to a side surface.

22. The support frame as claimed in claim 19, wherein the connecting unit has a retaining arm for supporting an add-on device which is arranged relative to a side surface.

23. The support frame as claimed in claim 13, wherein a third frame element has a third flange surface.

24. The support frame as claimed in claim 23, further comprising:
a flange plate arranged on the third flange surface, the flange plate being embodied as a module carrier for functional enhancements of the control panel.

25. The support frame as claimed in claim 13, further comprising:
a cooling surface coupled to at least one frame element for cooling a component of an electronic module.

26. An operator control and monitoring device, comprising:
a support frame for supporting a control panel, the support frame having frame elements forming the support frame, the frame elements being embodied as external side surfaces forming a housing part; and
a securing unit for fixing the control panel inside the support frame,
wherein a part of a first frame element has a first flange surface for flange-mounting the first frame element onto a support arm having a second flange surface.

27. The operator control and monitoring device as claimed in claim 26, further comprising:
a cover placed onto the support frame and arranged in a sealing manner around the first flange surface, wherein the control panel, the side surfaces and the cover form a structural unit.

28. The operator control and monitoring device as claimed in claim 26, further comprising:
a connecting unit arranged between the first flange surface and the second flange surface, the connecting unit being embodied with retaining arms for supporting add-on devices which are arranged essentially relative to the side surfaces.

29. The operator control and monitoring device as claimed in claim 27, further comprising:
a connecting unit arranged between the first flange surface and the second flange surface, the connecting unit being embodied with retaining arms for supporting add-on devices which are arranged essentially relative to the side surfaces.

30. The operator control and monitoring device as claimed in claim 26, wherein the control panel is a touch screen.

31. The operator control and monitoring device as claimed in claim 27, wherein the control panel is a touch screen.

32. The operator control and monitoring device as claimed in claim 28, wherein the control panel is a touch screen.
